(19) United States
(12) Patent Application Publication
(10) Pub. No.: US 2012/0161575 A1
(43) Pub. Date: Jun. 28, 2012

(54) STACK-TYPE BETA BATTERY GENERATING CURRENT FROM BETA SOURCE AND METHOD OF MANUFACTURING THE SAME

(75) Inventors: Byoung Gun CHOI, Daegu (KR); Jung Bum Kim, Daejeon (KR); In Gi Lim, Daejeon (KR); Chang Hee Hyoung, Daejeon (KR); Hyung Il Park, Daejeon (KR); Kyung Hwan Park, Daejeon (KR); Tae Young Kang, Seoul (KR); Sung Eun Kim, Seoul (KR); Jung Hwan Hwang, Daejeon (KR); Tae Wook Kang, Daejeon (KR); Kyung Soo Kim, Daejeon (KR); Sung Weon Kang, Daejeon (KR)

(73) Assignee: Electronics and Telecommunications Research Institute, Daejeon (KR)

(21) Appl. No.: 13/302,353

(22) Filed: Nov. 22, 2011

(30) Foreign Application Priority Data
Dec. 22, 2010 (KR) 10-2010-0132907

(51) Int. Cl. G21H 1/06; H01L 31/18

(52) U.S. Cl. 310/303; 438/56; 257/E31.125

(57) ABSTRACT

Provided are a stack-type beta battery generating a current from a beta source and a method of manufacturing the same. The method includes forming an oxide mask in a predetermined pattern on a surface of a substrate, forming a plurality of recesses by etching a region without the oxide mask from the substrate, removing the oxide mask and forming a PN-junction layer on the substrate, forming a first electrode on the PN-junction layer and forming a second electrode on another surface of the substrate, and forming a unit module by stacking a radioisotope layer on the PN-junction layer, the radioisotope layer emitting a beta ray. The beta battery can improve efficiency per unit area than a single layered beta battery by the number of stacked PN-junctions, and the process is simpler than a pore-forming process using DRIE, and manufacturing costs and time can be saved.

### CROSS-REFERENCE TO RELATED APPLICATIONS

The present application claims priority to Korean patent application number 10-2010-0132907, filed on Dec. 22, 2010, which is incorporated by reference in its entirety.

### BACKGROUND OF THE INVENTION

The present invention relates to a stack-type beta battery generating a current from a beta source and a method of manufacturing the stack-type beta battery.

Beta batteries use charges generated from a semiconductor device with a dose of radiation generated from isotopes to generate power. That is, beta batteries generate electron-hole pairs from a depletion layer of a PN-junction by using the energy of beta rays emitted by fission of radioisotopes, and thus, function as electrical power sources.

The number of electron-hole pairs per unit area or volume should be increased to increase the efficiency of a beta battery having a limited beta source. FIG. 1 illustrates a cross-sectional view of a beta battery including trenches formed using a deep reactive ion etching (DRIE) process to improve the efficiency of a beta battery in the related art.

Referring to FIG. 1, a diode structure 430 includes a semiconductor 302 that has a p-type region 408, an n-type region 410, and junction regions 412 and 427. A first contact 414 connects the p-type region 408 to a load 422, and a second contact 420 contacts a surface region 418 to connect the n-type region 410 to the load 422.

A surface 424 may be etched at a predetermined angle 428, and a film layer 306 may be applied on the surface 424. Holes 304 have right-angled tetragonal column shape with a predetermined depth 426 and a predetermined width 425. The holes 304 increase the number of electron-hole pairs per unit area or volume.

However, it is difficult to manufacture the beta battery configured as described above. Thus, a beta battery that has a larger area and a larger volume and can be more easily manufactured is needed.

The related art as described above may have been possessed to draw the present invention, or be technical information acquired in a process of drawing the present invention. Furthermore, the related art may not have been published before the application of the present invention.

### SUMMARY OF THE INVENTION

Embodiments of the present invention are directed to a stack-type beta battery generating a current from a beta source and a method of manufacturing the stack-type beta battery, in which PN-junction structures having a pyramid shape are stacked to increase the efficiency of the beta battery.

Embodiments of the present invention are also directed to a stack-type beta battery generating a current from a beta source and a method of manufacturing the stack-type beta battery, in which PN-junction structures having a pyramid shape using a wet etching process are simpler and can be more efficiently reproduced than using a pore-forming process with DRIE, and the PN-junction structures are stacked to absorb beta rays from both sides, thereby further improving the efficiency.

In one embodiment, a method of manufacturing a beta battery includes: forming an oxide mask in a predetermined pattern on a surface of a substrate; forming a plurality of recesses by wet-etching a region without the oxide mask from the substrate; removing the oxide mask and forming a PN-junction layer on the substrate; forming a first electrode on the PN-junction layer and forming a second electrode on another surface of the substrate; and forming a unit module by stacking a radioisotope layer on the PN-junction layer, the radioisotope layer emitting a beta ray.

The forming of the PN-junction layer may include implanting n-type impurity ions in the substrate that is a p-type substrate.

The forming of the PN-junction layer comprises diffusing n-type impurity ions in the substrate that is a p-type substrate.

The method may further include providing the unit module in plurality and stacking the unit modules with the recesses facing each other.

The recess formed in the substrate may have a triangle cross-section. The recess formed in the substrate may have a reverse pyramid shape.

The forming of the unit module may include stacking the radioisotope layer in a flat form on the PN-junction layer. The forming of the unit module may include stacking the radioisotope layer to conform with the recess formed in the substrate.

In another embodiment, a beta battery includes: a substrate comprising a plurality of recesses in a surface thereof, the recesses being etched using an oxide mask; a PN-junction layer disposed on the surface of the substrate provided with the recesses; a first electrode disposed on the PN-junction layer; a second electrode disposed on another surface of the substrate; and a unit module comprising a radioisotope layer stacked on the PN-junction layer to emit a beta ray, wherein the unit module is provided in plurality, and the unit modules are stacked with the recesses facing each other.

The recess formed in the substrate may have a reverse pyramid shape. The radioisotope layer may be stacked to conform with the recess formed in the substrate.

### BRIEF DESCRIPTION OF THE DRAWINGS

FIG. 1 illustrates a cross-sectional view of a beta battery including trenches formed using a deep reactive ion etching (DRIE) in the related art.

FIGS. 2 and 3 are cross-sectional views illustrating a process of manufacturing a beta battery according to an embodiment of the present invention.

FIG. 4 is a cross-sectional view illustrating a beta battery according to an embodiment of the present invention.

FIG. 5 is a cross-sectional view illustrating a final product of beta batteries including PN-junction structures with flat radioisotope layers according to an embodiment of the present invention.

FIG. 6 is a cross-sectional view illustrating a final product of beta batteries including PN-junction structures with radioisotope layers according to an embodiment of the present invention.

FIG. 7 illustrates a method of manufacturing a beta battery according to an embodiment of the present invention.

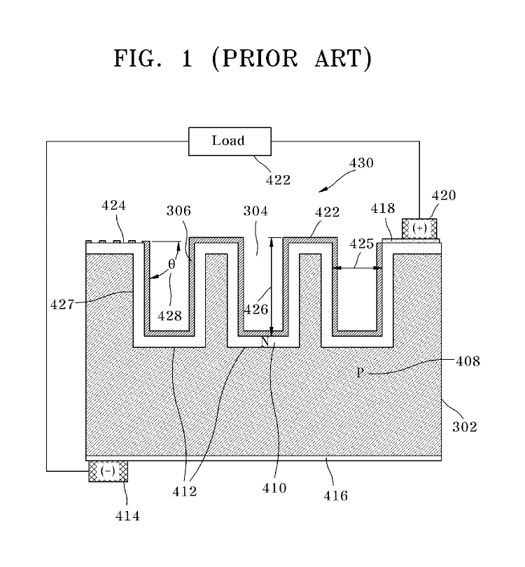

### DESCRIPTION OF SPECIFIC EMBODIMENTS

Hereinafter, a stack-type beta battery generating a current from a beta source and a method of manufacturing the same in accordance with the present invention will be described in detail with reference to the accompanying drawings.

The invention may, however, be embodied in many different forms and should not be construed as being limited to the embodiments set forth herein; rather, these embodiments are provided so that this disclosure will be thorough and complete, and will fully convey the concept of the invention to those skilled in the art.

Also, though terms like a first and a second are used to describe various members, components, regions, layers, and/or portions in various embodiments of the present invention, the members, components, regions, layers, and/or portions are not limited to these terms. Therefore, a member, a component, a region, a layer, or a portion referred to as a first member, a first component, a first region, a first layer, or a first portion in an embodiment can be referred to as a second member, a second component, a second region, a second layer, or a second portion in another embodiment. The word ‘and/or’ means that one or more or a combination of relevant constituent elements is possible.

Like reference numerals refer to like elements throughout, and thus, repeated descriptions thereof will be omitted. Moreover, detailed descriptions related to well-known functions or configurations will be ruled out in order not to unnecessarily obscure subject matters of the present invention.

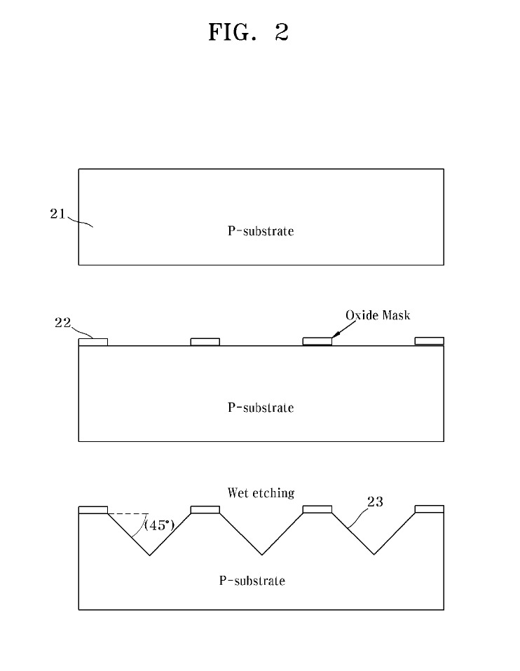

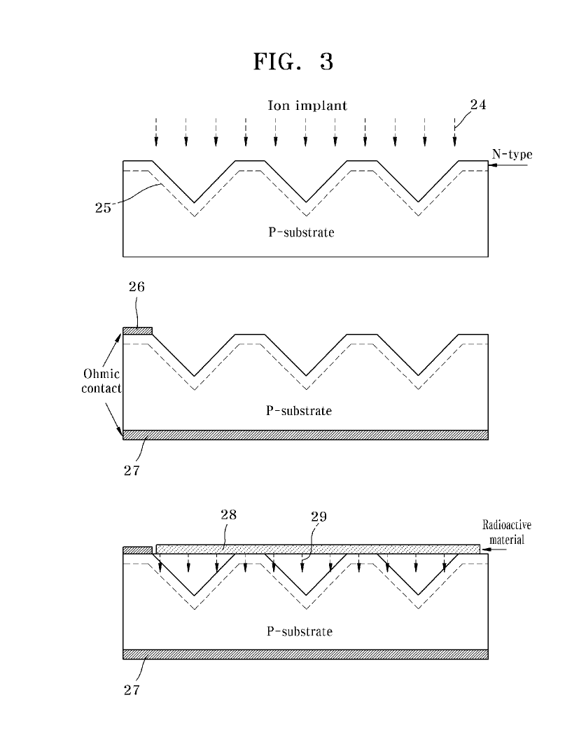

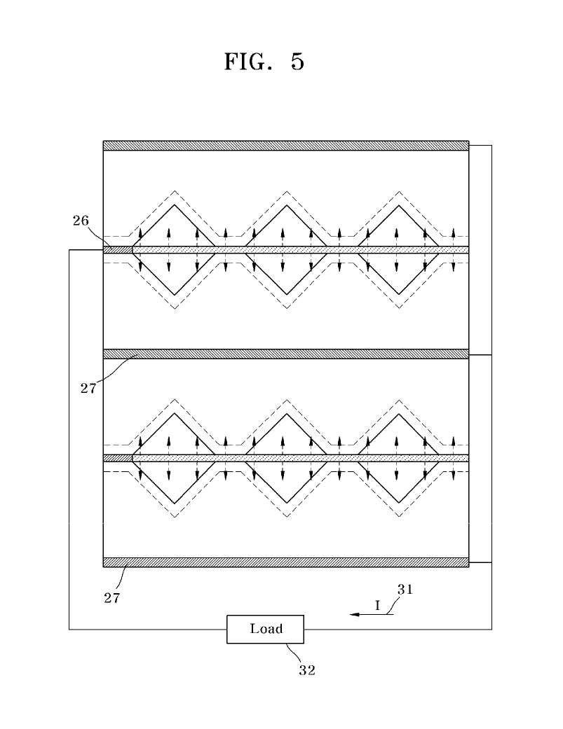

FIGS. 2 and 3 are cross-sectional views illustrating a process of manufacturing a beta battery according to an embodiment of the present invention. A substrate 21, an oxide mask 22, reverse pyramid recesses 23, n-type impurity ions 24, a PN-junction layer 25, a first metal 26, a second metal 27, a radioisotope layer 28, and beta rays 29 are illustrated in FIGS. 2 and 3, and a current 31 and a load 32 are illustrated in FIG. 5.

According to the current embodiment, a plurality of recesses are formed in the substrate 21 to form a beta battery having a large surface area. Especially, since unit modules are stacked, efficiency per unit area can be maximized.

The oxide mask 22 for wet etching is formed at specific positions on the substrate 21 that is a flat p-type silicon substrate, and then, the reverse pyramid recesses 23 are formed through the wet etching. Then, the oxide mask 22 is removed and the n-type impurity ions 24 are implanted to the substrate 21 to form the PN-junction layer 25.

The reverse pyramid recesses 23 may have a triangle cross-section and a 3-dimensional reverse pyramid shape.

The first and second metals 26 and 27 are deposited on an n-type semiconductor and a p-type semiconductor, respectively, to form electrodes. The first and second metals 26 and 27 may be in ohmic contact with the PN-junction layer 25. The first and second metals 26 and 27 may function as electrodes of the beta battery according to the current embodiment.

Then, the radioisotope layer 28 that is flat and emits the beta rays 29 is placed on the PN-junction layer 25 to form a unit module. The unit module generates electron-hole pairs from a depletion layer of a PN-junction by using the energy of the beta rays 29 emitted by fission of the radioisotope layer 28, and thus, functions as a battery.

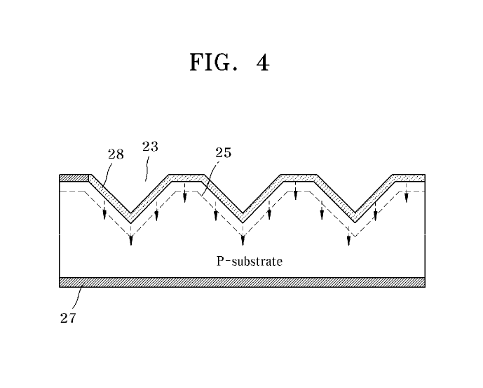

FIG. 4 is a cross-sectional view illustrating a beta battery according to an embodiment of the present invention. Referring to FIG. 4, the radioisotope layer 28 is stacked on a surface of the substrate 21 in the reverse pyramid recesses 23. According to the current embodiment, when a stacked amount of the radioisotope layer 28 increases, and a contact area between the radioisotope layer 28 and the PN-junction layer 25 increases, the capacity of the beta battery can increase.

FIG. 5 is a cross-sectional view illustrating a final product of beta batteries according to an embodiment of the present invention.

Referring to FIG. 5, the beta battery as a unit module illustrated in FIGS. 2 and 3 is provided in plurality, and the beta batteries are stacked in a multi layer to improve energy conversion efficiency. The beta batteries absorb beta electrons emitted from the radioisotope layers 28 that are flat, to apply the current 31 generated from the beta batteries to the load 32. That is, the current 31 flows from the second metal 27 to the first metal 26.

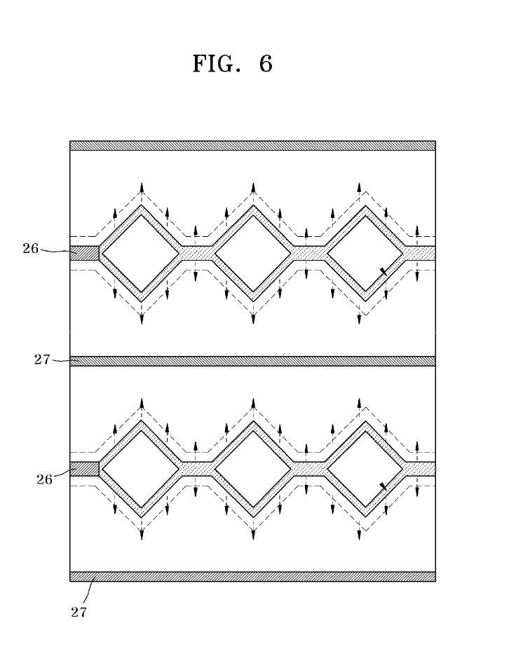

FIG. 6 is a cross-sectional view illustrating a final product of beta batteries according to an embodiment of the present invention, in which radioisotope layers 41 are deposited on the PN-junction layers 25.

Referring to FIG. 6, the unit module illustrated in FIG. 4 is provided in plurality, and the unit modules are stacked with recesses facing each other. According to the current embodiment, since the unit modules are stacked with the recesses facing each other, and the radioisotope layers 41 are stacked to conform with the recesses, electricity generating efficiency per unit area can be increased.

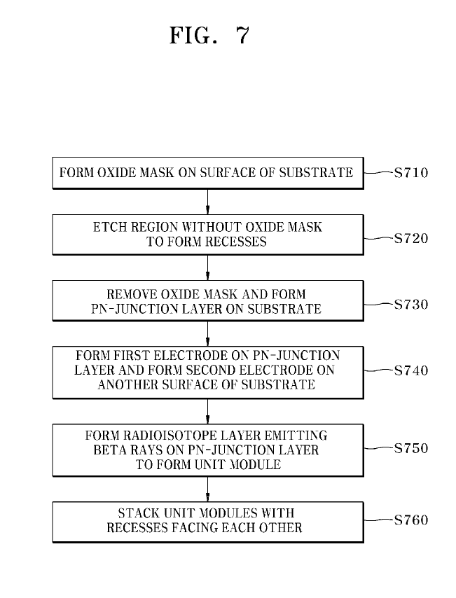

FIG. 7 illustrates a method of manufacturing a beta battery according to an embodiment of the present invention.

In operation S710, an oxide mask is formed in a predetermined pattern on a surface of a substrate. In operation S720, the substrate is removed in a region without the oxide mask to form a plurality of recesses. The recesses may have a triangle cross-section and a 3-dimensional reverse pyramid shape. In operation S730, the oxide mask is removed and a PN-junction layer is formed on the substrate.

In operation S740, a first electrode is formed on the PN-junction layer, and a second electrode is formed on another surface of the substrate.

In operation S750, a radioisotope layer that emits beta rays is formed on the PN-junction layer to form a beta battery as a unit module. At this point, the radioisotope layer may be flat to be stacked on the PN-junction layer, or be stacked to conform with the recesses disposed in the substrate. In operation S760, the beta battery is provided in plurality, and the beta batteries are stacked with the recesses facing each other to form a stacked structure of the beta batteries.

Since the types and functions of the substrates and typical battery manufacturing processes are well known to those skilled in the art, detailed descriptions thereof will be omitted here.

The stack-type beta battery generating a current from the beta source and the method of manufacturing the same can improve efficiency per unit area than a single layered beta battery by the number of stacked PN-junctions, and the process is simpler than a pore-forming process using DRIE, and manufacturing costs and time can be saved.

While the present invention has been described with respect to the specific embodiments, it will be apparent to those skilled in the art that various changes and modifications may be made without departing from the spirit and scope of the invention as defined in the following claims.

What is claimed is:

1. A method of manufacturing a beta battery, the method comprising:
forming an oxide mask in a predetermined pattern on a surface of a substrate;
forming a plurality of recesses by wet-etching a region without the oxide mask from the substrate;
removing the oxide mask and forming a PN-junction layer on the substrate;
forming a first electrode on the PN-junction layer and forming a second electrode on another surface of the substrate; and
forming a unit module by stacking a radioisotope layer on the PN-junction layer, the radioisotope layer emitting a beta ray.

2. The method of claim 1, wherein the forming of the PN-junction layer comprises implanting n-type impurity ions in the substrate that is a p-type substrate.

3. The method of claim 1, wherein the forming of the PN-junction layer comprises diffusing n-type impurity ions in the substrate that is a p-type substrate.

4. The method of claim 1, further comprising providing the unit module in plurality and stacking the unit modules with the recesses facing each other.

5. The method of claim 1, wherein the recess formed in the substrate has a triangle cross-section.

6. The method of claim 1, wherein the recess formed in the substrate has a reverse pyramid shape.

7. The method of claim 1, wherein the forming of the unit module comprises stacking the radioisotope layer in a flat form on the PN-junction layer.

8. The method of claim 1, wherein the forming of the unit module comprises stacking the radioisotope layer to conform with the recess formed in the substrate.

9. A beta battery comprising:
a substrate comprising a plurality of recesses in a surface thereof, the recesses being etched using an oxide mask;
a PN-junction layer disposed on the surface of the substrate provided with the recesses;
a first electrode disposed on the PN-junction layer;
a second electrode disposed on another surface of the substrate; and
a unit module comprising a radioisotope layer stacked on the PN-junction layer to emit a beta ray,
wherein the unit module is provided in plurality, and
the unit modules are stacked with the recesses facing each other.

10. The beta battery of claim 9, wherein the recess formed in the substrate has a reverse pyramid shape.

11. The beta battery of claim 9, wherein the radioisotope layer is stacked to conform with the recess formed in the substrate.
